(19) United States
(12) Patent Application Publication
(10) Pub. No.: US 2026/0184065 A1
(43) Pub. Date: Jul. 2, 2026

(54) PRINTING PAD, METHOD OF MANUFACTURING A PRINTING PAD, METHOD OF MANUFACTURING A COVER WINDOW USING THE PRINTING PAD

(71) Applicant: Samsung Display Co., Ltd., Yongin-Si (KR)

(72) Inventor: KYOUNGIN LEE, Yongin-si (KR)

(21) Appl. No.: 19/326,734

(22) Filed: Sep. 12, 2025

(30) Foreign Application Priority Data
Dec. 31, 2024 (KR) 10-2024-0202007

(51) Int. Cl. B41F 17/00; B29C 37/00; B29K 21/00; B29L 31/00; B41M 1/40; H05K 5/03

(52) U.S. Cl. CPC B41F 17/001; B29C 37/0053; B41M 1/40; B29K 2021/003; B29K 2995/007; B29L 2031/767; H05K 5/03

(57) ABSTRACT

A printing pad is disclosed that includes a first part including a bottom surface parallel to a plane defined by a first direction and a second direction crossing the first direction, a first upper surface facing the bottom surface, and a first side surface connecting the bottom surface and the first upper surface, and a second part including a second upper surface facing the first upper surface, a second side surface connecting the first upper surface to the second surface, and a contact part having a radius of curvature that is equal to a minimum curvature radius of a target object to be processed.

### CROSS-REFERENCE TO RELATED APPLICATION(S)

The present application claims priority to and the benefit of Korean Patent Application No. 10-2024-0202007 filed on Dec. 31, 2024 in the Korean Intellectual Property Office (KIPO), the entire disclosure of which is incorporated herein by reference.

### BACKGROUND

### 1. Field

Embodiments relate to a printing pad for manufacturing a cover window. More particularly, embodiments relate to a printing pad with improved printing performance, a manufacturing method of a printing pad, and a manufacturing method of a cover window using the printing pad.

### 2. Description of the Related Art

With the development of information technology, display devices, which connect users to information, play an important role in users' daily lives. As a result, the use of display devices such as liquid crystal display devices (“LCD”s), organic light-emitting display devices (“OLED”s), and plasma display devices (“PDP”s) is increasing.

Display devices and electronic devices that include the display device include a cover window to protect against an external impact. Patterns may be formed on the cover window to add design. The patterns may be formed by transferring an ink onto the cover window using a printing pad.

### SUMMARY

This disclosure provides a printing pad.

This disclosure provides a method of manufacturing a printing pad.

This disclosure provides a method for manufacturing a cover window using the printing pad.

A printing pad according to an embodiment of the disclosure includes a first part including a bottom surface parallel to a plane defined by a first direction and a second direction crossing the first direction, a first upper surface facing the bottom surface, and a first side surface connecting the bottom surface and the first upper surface and a second part including a second upper surface facing the first upper surface, a second side surface connecting the first upper surface to the second surface, and a contact part having a radius of curvature that is equal to a minimum curvature radius of a target object.

In an embodiment, the second side surface may increase in width, which is measured in the second direction, in going from the second upper surface to the first upper surface, and forming a preselected angle with respect to a virtual normal line perpendicular to the bottom surface.

In an embodiment, the selected angle between the virtual normal line and the second side surface may be about 2 degrees to about 4 degrees, inclusive.

In an embodiment, the first part may have a first Shore A hardness, the second part may have a second Shore A hardness, and the second Shore A hardness may be lower than the first Shore A hardness.

In an embodiment, the second Shore A hardness may be about 70% to about 90% of the first Shore A hardness.

In an embodiment, the first part and the second part may include an elastomer.

In an embodiment, the first part and the second part may contain silicone.

A method of manufacturing a printing pad according to an embodiment of the disclosure includes setting a design criteria including a minimum curvature radius of a target object to be processed, forming a second part including a second upper surface, a second side surface extending from the second upper surface in a third direction, and a contact part having a radius of curvature that is equal to a minimum curvature radius of the target object, and forming a first part on the second part, the first including a first upper surface facing the second upper surface in the third direction, a bottom surface facing the first upper surface in the third direction and parallel to a plane defined by a first direction and a second direction that cross the third direction, and a first side surface connecting the bottom surface and the first upper surface.

In an embodiment, the second side surface may be formed so that a width measured in the second direction increases in going from the contact part to the first upper surface.

In an embodiment, the second side surface may be formed to have an angle of about 2 degrees to about 4 degrees, inclusive, with a virtual normal line parallel to the third direction, from the contact part to the first upper surface.

In an embodiment, the first part and the second part may be formed by supplying an elastomer in a mold.

In an embodiment, the first part may have a first Shore A hardness, the second part may have a second Shore A hardness, and the second Shore A hardness may be lower than the first Shore A hardness.

In an embodiment, the second Shore A hardness may be about 70% to about 90% of the first Shore A hardness.

In an embodiment, the first Shore A hardness and the second Shore A hardness may be controlled by an addition of silicone oil to the first part and the second part, respectively.

A method of manufacturing a cover window according to an embodiment of the disclosure includes providing an ink to an ink plate, placing a target object on a stage, transferring the ink to the target object using a printing pad including a first part and a second part, the first part including a bottom surface parallel to a plane defined by a first direction and a second direction crossing the first direction, a first upper surface facing the bottom surface, and a first side surface connecting the bottom surface and the first upper surface, and the second part including a second upper surface facing the first upper surface, a second side surface connecting the first upper surface and the second surface, and a contact part having a radius of curvature that is equal to a minimum curvature radius of the target object.

In an embodiment, a second Shore A hardness of the second part may be lower than a first Shore A hardness of the first part.

In an embodiment, the target object may include glass, and the glass may be a cover window for a display panel.

In an embodiment, the target object may be coupled with an outer case in which a space is defined to receive the target object, and the target object combined with the outer case may be one of an image display, a wearable electronic device, or a vehicle electronic device including a display module.

In an embodiment, the target object may include: a display surface and a side surface extending in the third direction that crosses the first direction and the second direction, and the printing pad transfers the ink onto a portion of the display surface and an entire sidewall.

In an embodiment, the ink may include a light-shielding material.

A printing pad with improved printing performance, a manufacturing method of the printing pad, manufacturing apparatus including the printing pad for a cover window, and manufacturing method of the cover window using the same, according to the embodiments of the disclosure may enhance a printing quality by using the printing pad of a form that may be deformed to a minimum curvature part included in the object to be processed.

Here, the printing pad may include a printing part (the second part) and a connection part (the first part). The hardness of the second part may be about 70% to about 90% of the hardness of the first part. As the first part has a greater hardness than the second part, the first part may support the second part more stably. On the other hand, as the second part has a relatively smaller hardness than the first part, the second part may be sufficiently modified to transfer the ink up to the minimum curvature part.

The side surface of the second part of the printing pad may have the angle of about 2 degrees to about 4 degrees with the virtual normal line. As a result, the ink may be transferred to the portion of the display surface and the entire sidewall with just two strokes. In addition, the ink may be transferred to a minimum curvature part of the cover window to prevent an occurrence of a light leakage phenomenon by an un-printed part.

### BRIEF DESCRIPTION OF THE VIEWS

The above and other exemplary embodiments, advantages and features of this disclosure will become more apparent by describing in further detail exemplary embodiments thereof with reference to the accompanying views, in which:

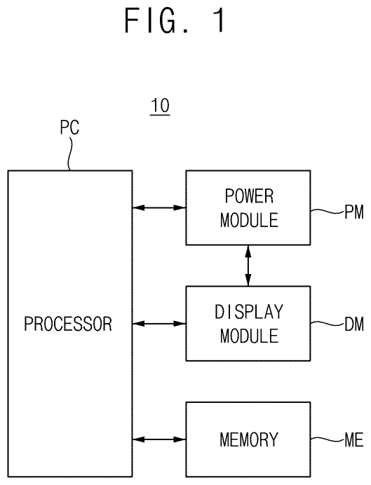

FIG. 1 is a block diagram illustrating an electronic device according to one or more embodiments.

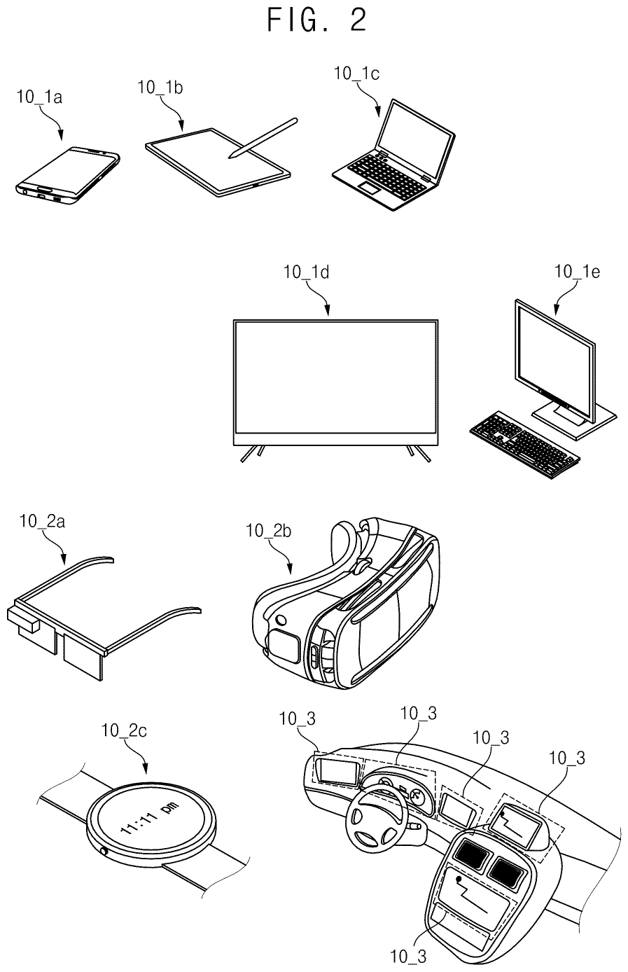

FIG. 2 is a schematic diagram of an electronic device according to one or more embodiments.

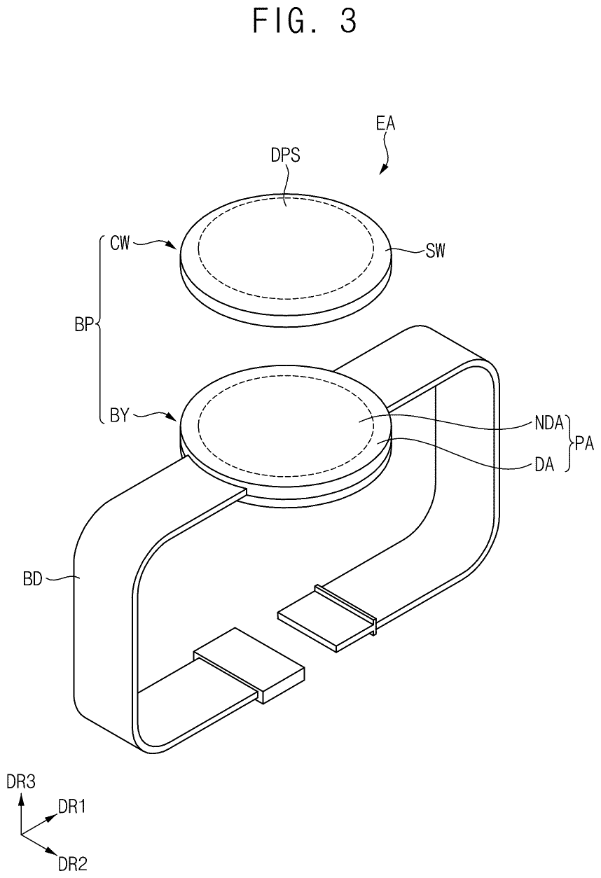

FIG. 3 is an exploded perspective view illustrating the electronic device according to an embodiment.

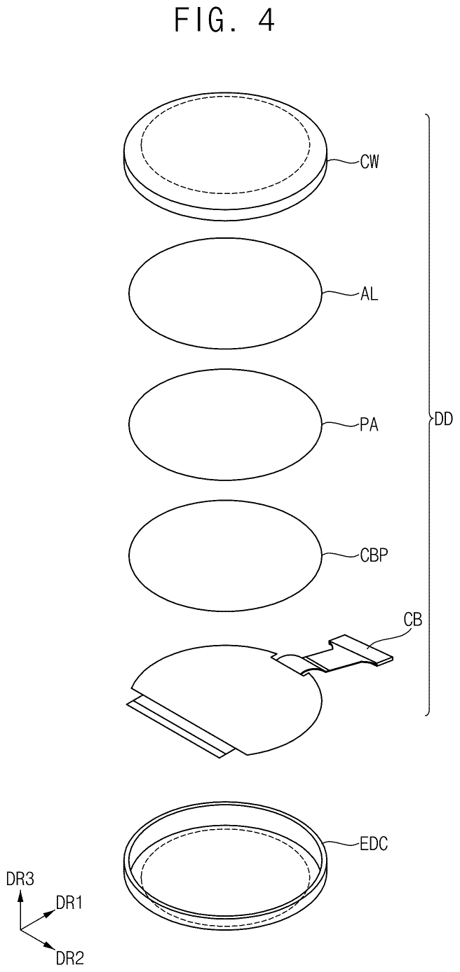

FIG. 4 is an exploded perspective view illustrating an example of a display device according to an embodiment of the disclosure.

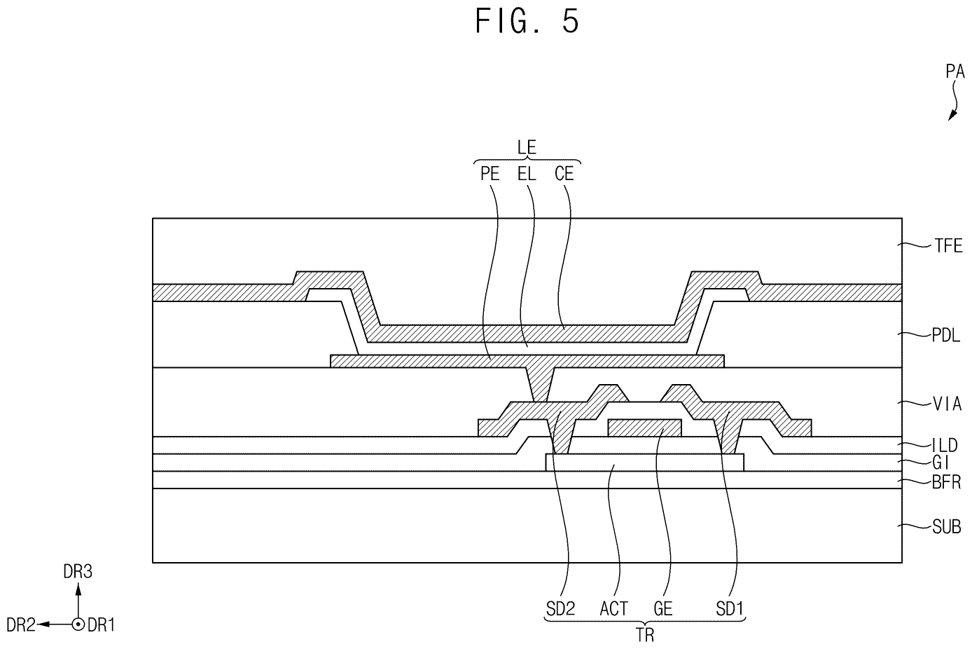

FIG. 5 is a cross-sectional view of a portion of a display panel included in the display device of FIG. 4.

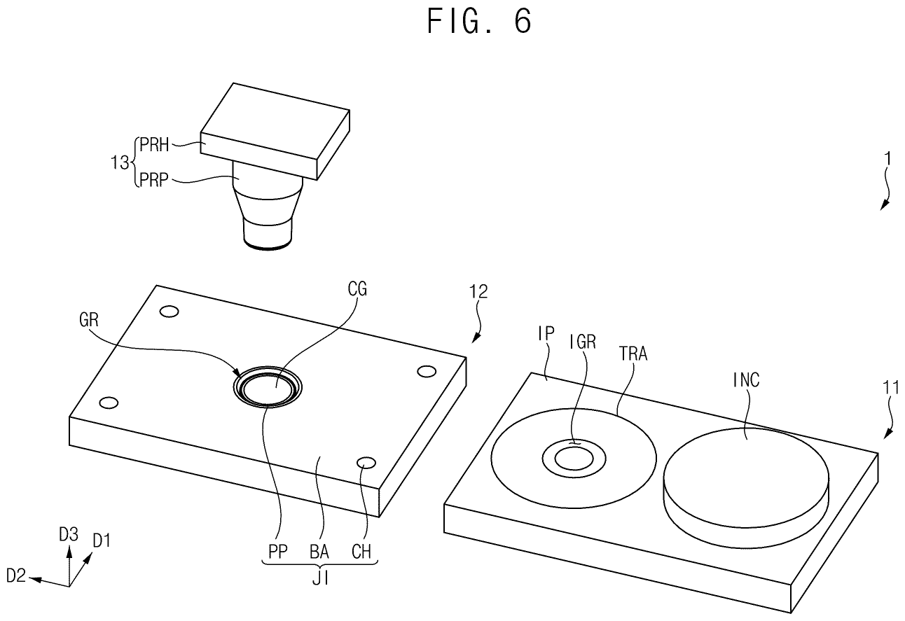

FIG. 6 is a view illustrating the manufacturing apparatus of the cover window according to an embodiment of the disclosure.

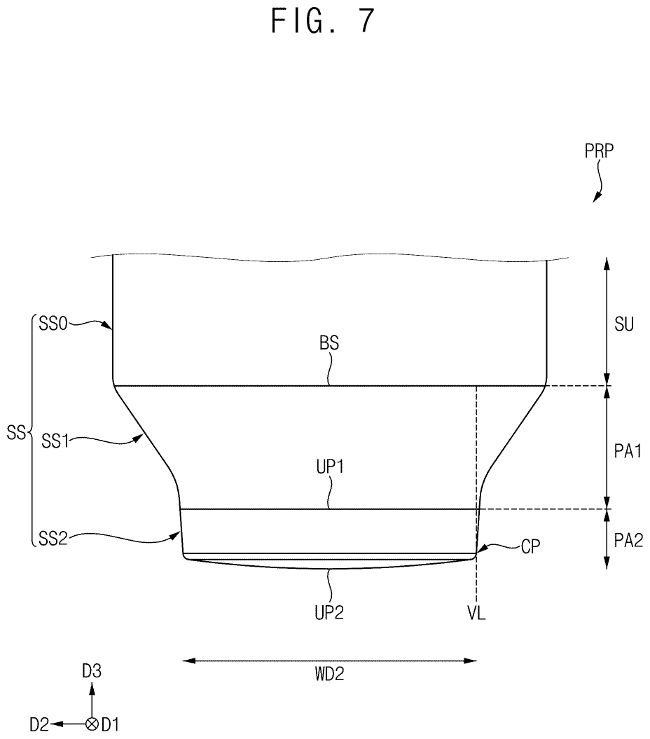

FIG. 7 is a view illustrating the printing pad included in the manufacturing apparatus of the cover window of FIG. 6.

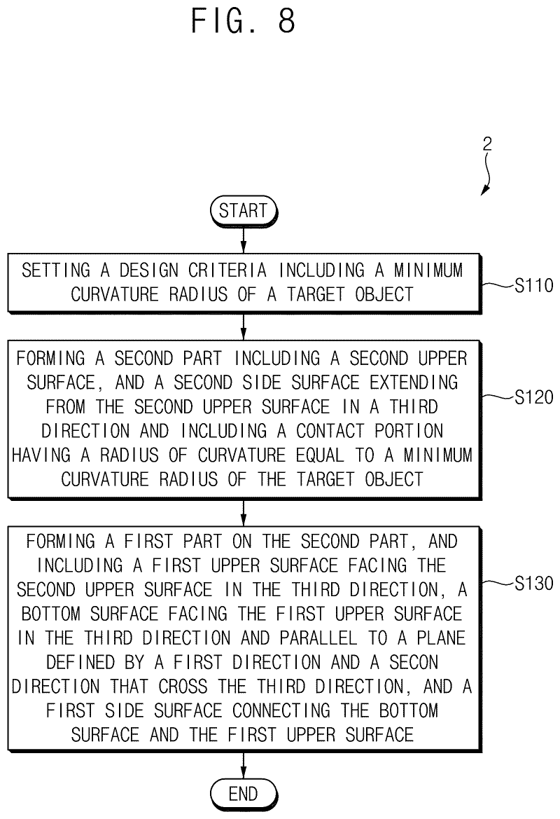

FIG. 8 is a flow chart illustrating the manufacturing method of the printing pad according to an embodiment of the disclosure.

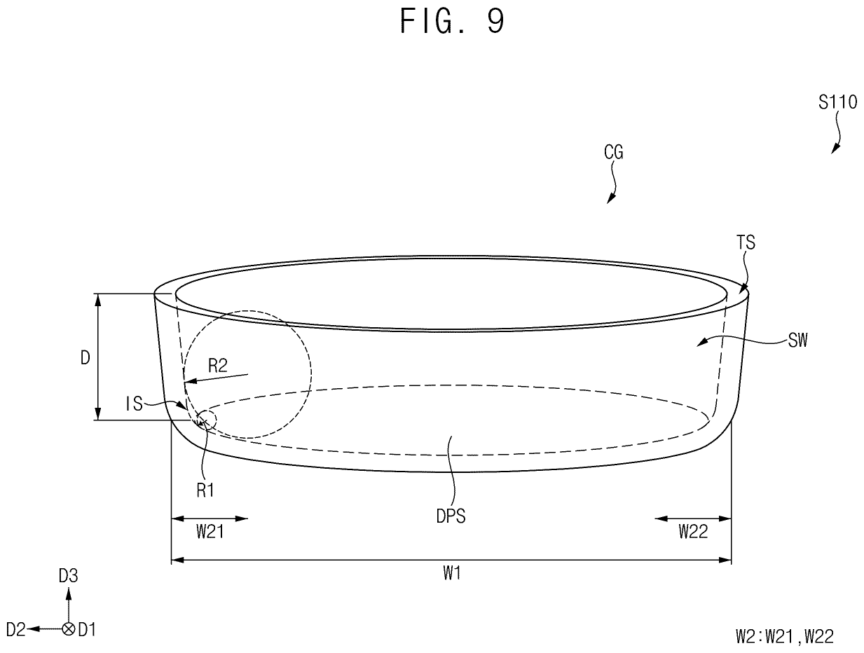

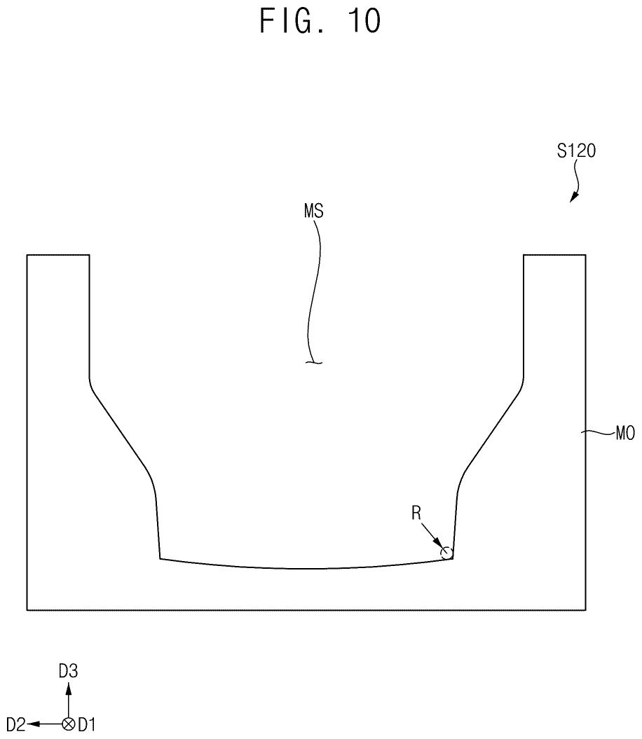

FIGS. 9, 10, 11, 12, 13, and 14 are views illustrating the manufacturing method of the printing pad of FIG. 8.

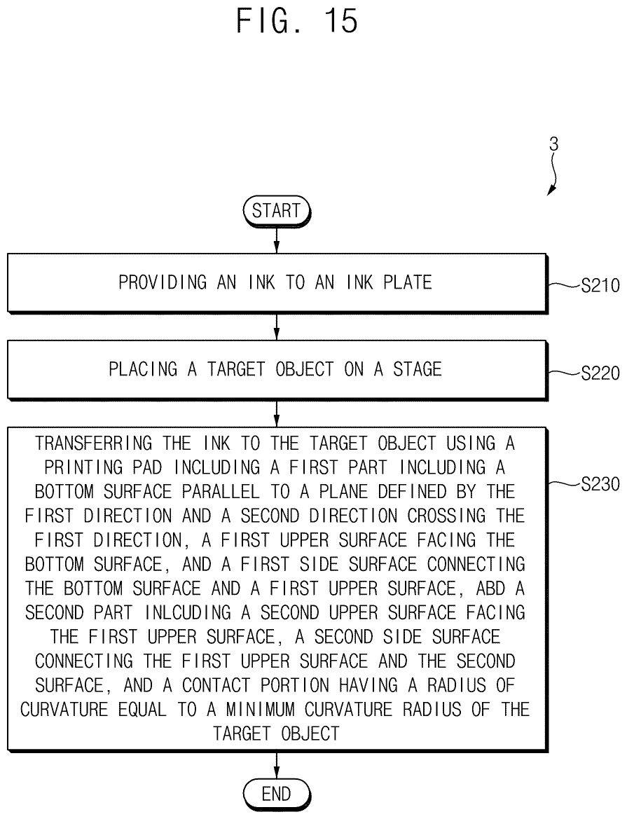

FIG. 15 is a flow chart illustrating the manufacturing method of the cover window using the manufacturing apparatus of the cover window of FIG. 6.

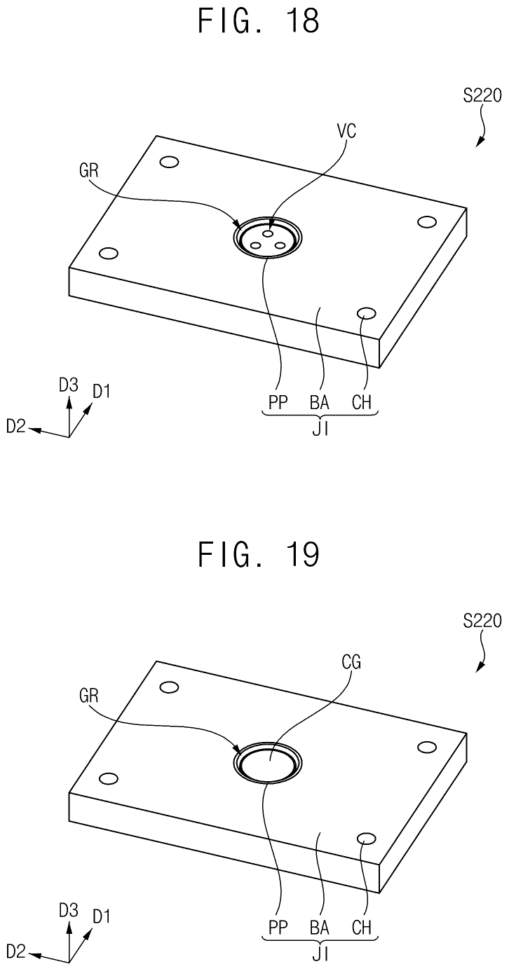

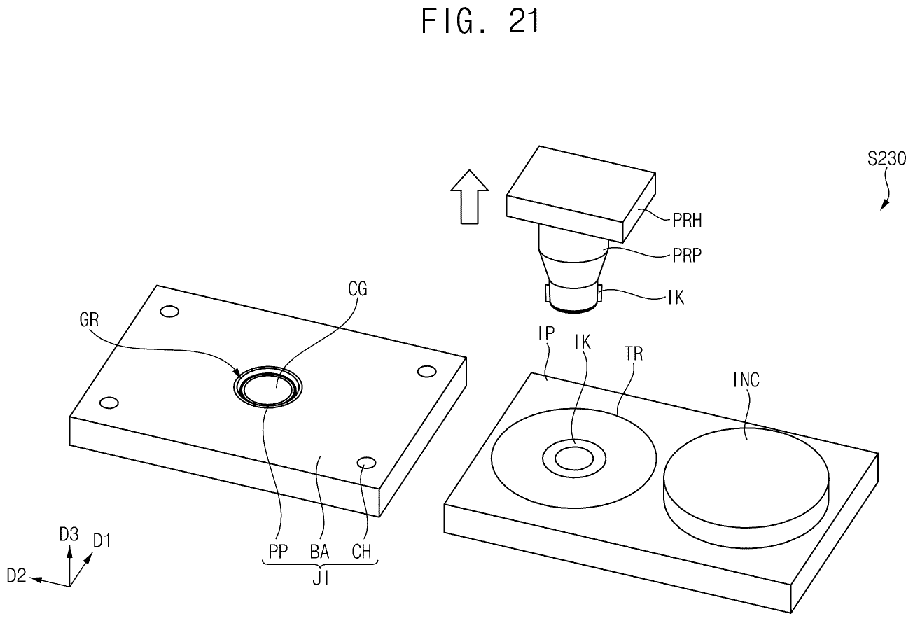

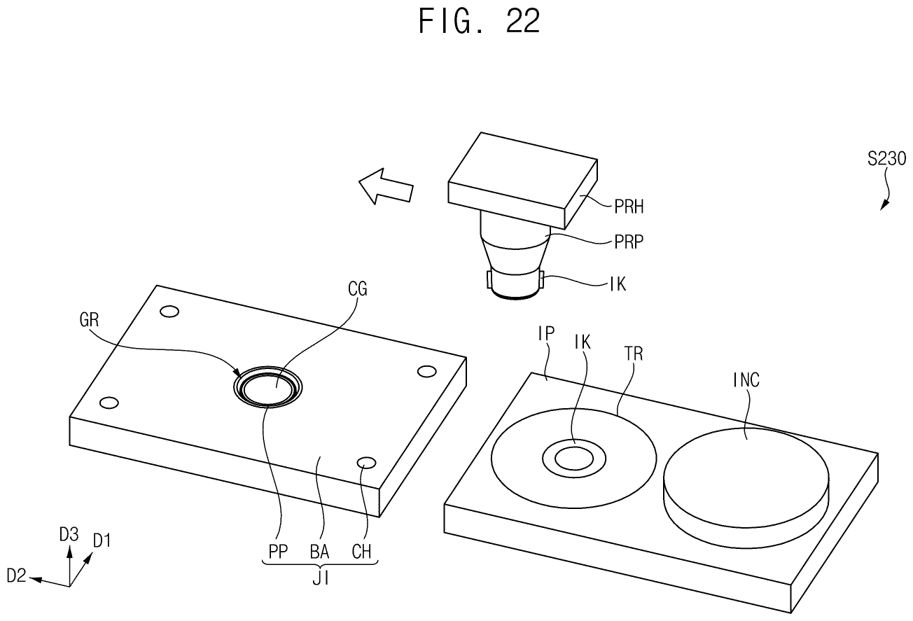

FIGS. 16, 17, 18, 19, 20, 21, 22, and 23 are views illustrating the manufacturing method of the cover window of FIG. 15.

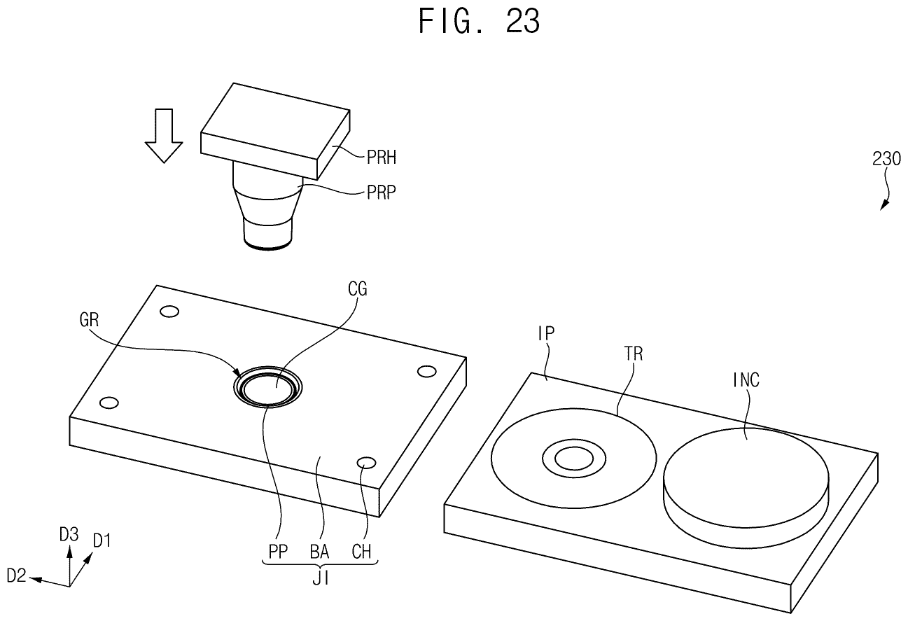

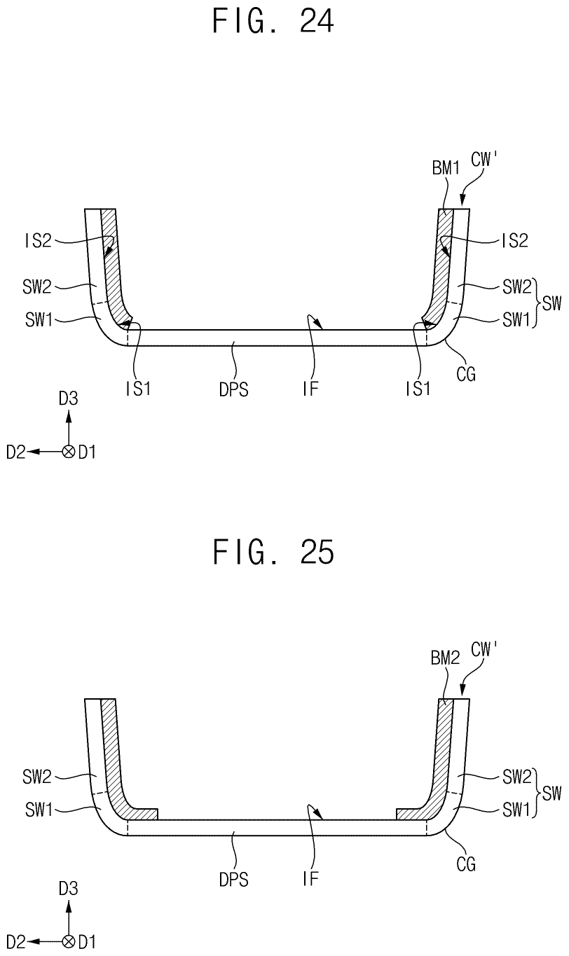

FIGS. 24, 25, 26, and 27 are views illustrating an effect of the printing pad according to embodiments of the disclosure.

### DETAILED DESCRIPTION OF THE EMBODIMENTS

Hereinafter, embodiments of the disclosure will be described in detail with reference to the accompanying views. Same reference numerals will be used for the same components in the views, and repeated descriptions of the same components will not be provided.

The display device according to one or more embodiments may be applied to a variety of electronic devices. The electronic apparatus according to one or more embodiments includes the aforementioned display device and may include a module or apparatus having other additional functions in addition to the display device.

FIG. 1 is a block diagram illustrating an electronic device according to one or more embodiments.

Referring to FIG. 1, an electronic device EA according to an embodiment may include a display module DM, a processor PC, a memory ME, and a power module PM.

The processor PC may include a central processing unit (“CPU”), an application processor (“AP”), a graphic processing unit (“GPU”), a communication processor (“CP”), an image signal processor (“ISP”), and/or a controller.

Data information necessary for operation of the processor PC or the display module DM may be stored in the memory ME. When the processor PC executes an application stored in the memory ME, an image data signal and/or an input control signal is transmitted to the display module DM, and the display module DM may process received signal and output image information through a display screen.

The power module PM may include a power supply module such as a power adapter and/or a battery device, and a power conversion module that converts power supplied by the power supply module to generate power desired or required for operation of the electronic device EA.

At least one of the components of the electronic device EA described above may be included in the display device according to the above-described embodiments. In addition, some of individual modules functionally included in one module may be included in the display device, and others may be provided separately from the display device. For example, the display device may include the display module DM, and the processor PC, the memory ME, and the power module PM may be provided in the form of another device in the electronic device EA other than the display device.

FIG. 2 is a schematic diagram of an electronic device according to one or more embodiments.

Referring to FIG. 2, one or more suitable electronic devices to which display devices according to one or more embodiments are applied may include not only electronic devices for image display such as a smartphone 10_1a, a tablet PC 10_1b, a laptop 10_1c, a TV 10_1d, a desk monitor 10_1e, and/or the like, but wearable electronic devices including display modules such as a smart glass 10_2a, a head mounted display 10_2b, a smart watch 10_2c, and/or the like, vehicle electronic device 10_3 including display modules such as on a vehicle's instrument panel, a center fascia, a center information display (“CID”) located on a dashboard, a room mirror display, and/or the like.

FIG. 3 is an exploded perspective view illustrating the electronic device according to an embodiment.

Referring to FIG. 3, an electronic device EA according to an embodiment of the disclosure may include a body part BP and a wearing part BD. FIG. 3 describes the electronic device EA as a smart watch, but the disclosure is not limited thereto. For example, the electronic device EA is subject to various modifications.

The body part BP, which may be a display device, may include a display panel PA and a cover window CW that is placed on the display panel PA.

For example, the display panel PA may include an organic light-emitting display panel, a liquid crystal display panel, a quantum dot display panel, a micro LED display panel, a nano LED display panel, or the like. However, the disclosure is not limited thereto.

The display panel PA may include a display area DA and a non-display area NDA. For example, the display area DA may display an image. The display area DA may include pixels PX. A front surface may mean a surface on which a light emitted from the plurality of pixels PX is displayed as the image. The front surface may be defined by a first direction DR1 and a second direction DR2. A back surface is more adjacent to an outer case (e.g., an outer case EDC of FIG. 4) than the front surface. The front and the back surfaces may be spaced in a third direction DR3.

For the sake of explanation, the third direction DR3 is also referred to as a thickness direction. For example, the first direction DR1, the second direction DR2, and the third direction DR3 may cross each other. For example, the first direction DR1, the second direction DR2, and the third direction DR3 may be perpendicular to each other.

The disclosure is not limited thereto. For example, the image may be displayed on the back surface, and in this case, the outer case EDC may be formed of a transparent material.

The non-display area NDA may surround the display area DA. For example, a shape of the display area DA may be substantially defined by the non-display area NDA.

FIG. 3 describes a planar shape of the display area DA as circular, but the disclosure is not limited thereto. For example, the planar shape of the display area DA may be various shapes, such as oval, rectangle with cut edges, rectangle, square, or the like.

The cover window CW may protect components placed at the bottom of the cover window CW from external environment, shocks, or the like. The cover window CW may be optically transparent. For example, the cover window CW may contain glass, transparent polymer, or the like.

The cover window CW may overlap with the display panel PA. For example, the cover window CW may be placed to cover the front surface of the display panel PA. For example, the cover window CW may be greater than the display panel PA. For example, the cover window CW may protrude outward than the display panel PA.

For example, the cover window CW may have a similar shape to the display panel PA in the plan view. FIG. 3 describes the planar shape of the cover window CW as circular, but the disclosure is not limited thereto. For example, depending on the planar shape of the display panel PA, the planar shape of the cover window CW may be variously modified.

In an embodiment, the cover window CW may include a display surface DPS and the sidewall SW. In an embodiment, the sidewall SW may extend from the display surface DPS curving or sloping in the third direction DR3.

For example, the display surface DPS may be positioned in a center of the cover window CW. The display surface DPS may be generally flat. The display surface DPS may be the area corresponding to the display area DA of the display panel PA. For example, the display surface DPS may cover entire or a portion of the display area DA of the display panel PA.

For example, the sidewall SW may be placed around the display surface DPS. The sidewall SW may be a curved part extending from the display surface DPS. The sidewall SW may curve downward from an edge of the display surface DPS. In some embodiments a portion of the sidewall SW may be curved with a predetermined curvature, and the rest may be flat. For example, a degree to which the sidewall SW is bent from the display surface DPS (i.e., angle) may be an obtuse angle. However, the disclosure is not limited thereto. For example, the angle may be either a right angle or an acute angle. For example, the surface may have different curvatures depending on the area.

The cover window CW may include a light-shielding pattern. In an embodiment, the light-shielding pattern included in the cover window CW may include a light-shielding material (e.g., a dye, a pigment, an opaque metal, or the like). The light-shielding pattern may be formed by a coating method. The light-shielding pattern may be placed overlapping with the non-display area NDA. However, the disclosure is not limited thereto. For example, The light-shielding pattern may include other materials. In addition, the light-shielding pattern may be formed in different ways. The light-shielding pattern may overlap with a portion of the display area DA. A detailed description of the cover window CW and the light-shielding pattern is described below.

The wearing part BD may be a part that secures the body part BP to a user's wrist, or the like. For example, the wearing part BD may include a band, strap, chain, bracelet, or the like.

FIG. 4 is an exploded perspective view illustrating an example of a display device according to an embodiment of the disclosure. FIG. 5 is a cross-sectional view of a portion of a display panel included in the display device of FIG. 4.

Referring to FIG. 4, the display device DD may include the cover window CW, an adhesive layer AL, a cover panel CBP, and a circuit board CB.

The cover panel CBP, the display panel PA, the adhesive layer AL, and the cover window CW may be sequentially arranged on the circuit board CB. For example, the circuit board CB, the cover panel CP, the display panel PA, the adhesive layer AL, and the cover window CW may be sequentially arranged along the third direction DR3.

For example, the cover window CW may have a dome shape. For example, the cover window CW may have the dome shape which is curved in the third direction DR3 such that the center portion is farther from the outer case EDC than the edge. The cover window CW has the dome shape, and may define an inner space. The cover window CW may accommodate components arranged below the cover window CW in the inner space.

The adhesive layer AL may be arranged below the cover window CW. The adhesive layer AL may couple the cover window CW and a component arranged below the adhesive layer AL. The adhesive layer AL may be optically transparent. For example, the adhesive layer AL may include an optically clear adhesive (“OCA”), an optically clear resin (“OCR”), or a pressure sensitive adhesive (“PSA”). Accordingly, influence of the adhesive layer AL on a visibility of an image generated from the display panel PA may be reduced.

The display panel PA may be arranged below the adhesive layer AL. For example, the display panel PA may be coupled to the cover window CW by the adhesive layer AL.

A space may be defined in the outer case EDC. The defined space accommodates the target object to be processed (e.g. the display panel PA and the cover window CW on the display panel). The target object may be, for example, the display device DD including the display module.

Referring to FIG. 5, the display panel PA may include a substrate SUB, a buffer layer BFR, a transistor TR, a gate insulating layer GI, an interlayer insulating layer ILD, a via insulating layer VIA, a light emitting element LE, a pixel defining layer PDL, and an encapsulation layer TFE. The transistor TR may include an active pattern ACT, a gate electrode GE, a first electrode SD1, and a second electrode SD2, and the light emitting element LE may include a pixel electrode PE, a light emitting layer EL, and a common electrode CE.

The substrate SUB may include a transparent material or an opaque material. For example, the substrate SUB may include plastic, glass, quartz, silicone, or the like. These may be used alone or in combination with each other.

The buffer layer BFR may be arranged on the substrate SUB. The buffer layer BFR may prevent metal atoms, impurities, or the like from diffusing into the transistor TR. The buffer layer BFR may include an inorganic material such as, for example, silicone oxide (“SiOₓ”), silicone nitride (“SiNₓ”), silicone oxynitride (“SiOₓN_{y}”), or the like. These may be used alone or in combination with each other.

The active pattern ACT may be arranged on the buffer layer BFR. The active pattern ACT may include a source area, a drain area, and a channel area between the source area and the drain area. The active pattern ACT may include a silicone semiconductor material or an oxide semiconductor material. Examples of the silicone semiconductor material may include amorphous silicone, polycrystalline silicone, or the like. Examples of the oxide semiconductor material may include indium gallium zinc oxide (“IGZO”), indium tin zinc oxide (“ITZO”), or the like. These may be used alone or in combination with each other.

The gate insulating layer GI may be arranged on the active pattern ACT, and may cover the active pattern ACT. The gate insulating layer GI may include an inorganic material such as, for example, silicone oxide, silicone nitride, silicone oxynitride, or the like. These may be used alone or in combination with each other.

The gate electrode GE may be arranged on the gate insulating layer GI. The gate electrode GE may overlap the channel area of the active pattern ACT in a plan view. The gate electrode GE may include a metal, an alloy, a conductive metal oxide, a conductive metal nitride, a transparent conductive material, or the like. These may be used alone or in combination with each other.

The interlayer insulating layer ILD may be arranged on the gate electrode GE, and may cover the gate electrode GE. The interlayer insulating layer ILD may include an inorganic material such as, for example, silicone oxide, silicone nitride, silicone oxynitride, or the like. These may be used alone or in combination with each other.

The first and second electrodes SD1 and SD2 may be arranged on the interlayer insulating layer ILD. The first and second electrodes SD1 and SD2 may be connected to the source area and the drain area of the active pattern ACT, respectively. For example, each of the first electrode SD1 and the second electrode SD2 may include a metal, an alloy, a conductive metal oxide, a conductive metal nitride, a transparent conductive material, or the like. These may be used alone or in combination with each other.

Accordingly, the transistor TR including the active pattern ACT, the gate electrode GE, the first electrode SD1, and the second electrode SD2 may be arranged on the substrate SUB.

The via insulating layer VIA may be arranged on the first and second electrodes SD1 and SD2, and may cover the first and second electrodes SD1 and SD2. The via insulating layer VIA may include an organic material such as, for example, phenol resin, acrylic resin, polyimide resin, polyamide resin, siloxane resin, epoxy resin, or the like. These may be used alone or in combination with each other.

The pixel electrode PE may be arranged on the via insulating layer VIA. The pixel electrode PE may be connected to the second electrode SD2 (or the first electrode SD1). The pixel electrode PE may include a metal, an alloy, a conductive metal oxide, a conductive metal nitride, a transparent conductive material, or the like. These may be used alone or in combination with each other.

The pixel defining layer PDL may be arranged on the via insulating layer VIA, and may cover at least a portion of the pixel electrode PE. The pixel defining layer PDL may define an opening exposing at least a portion of an upper surface of the pixel electrode PE. The pixel defining layer PDL may include an organic material or an inorganic material. For example, the pixel defining layer PDL may include an organic material such as, for example, epoxy resin, siloxane resin, or the like. For example, the pixel defining layer PDL may include an organic material or an inorganic material including a light blocking material having a black color.

The light emitting layer EL may be arranged on the pixel electrode PE. The light emitting layer EL may be arranged on the pixel electrode PE exposed by the pixel defining layer PDL. The light emitting layer EL may include a material which emits light of a selected color.

The common electrode CE may be arranged on the light emitting layer EL. The common electrode CE may include a metal, an alloy, a conductive metal oxide, a conductive metal nitride, a transparent conductive material, or the like. These may be used alone or in combination with each other.

Accordingly, the light emitting element LE including the pixel electrode PE, the light emitting layer EL, and the common electrode CE may be arranged on the substrate SUB. The light emitting element LE may be electrically connected to the transistor TR. The light emitting element LE may generate light corresponding to a driving current provided from the transistor TR. The transistor TR and the light emitting element LE may correspond to the pixels, respectively.

The encapsulation layer TFE may be arranged on the common electrode CE. The encapsulation layer TFE may protect the light emitting element LE from external oxygen, moisture, or the like. The encapsulation layer TFE may include at least one inorganic layer and at least one organic layer. For example, the encapsulation layer TFE may have a structure in which an inorganic layer and an organic layer are alternately stacked.

The cover panel CP may be arranged below the display panel PA. The cover panel CP may cover a lower surface of the display panel PA. The cover panel CP may have a single-layer structure or a multi-layer structure. For example, the cover panel CP may have a structure in which a cushion member, a heat dissipating member, a conductive thin film, or the like are stacked. The cushion member may absorb impact such that the impact is not applied (or is partially applied) to the display panel PA. The heat dissipating member may prevent heat applied to the display panel PA, or may diffuse heat generated from the display panel PA. The conductive thin film may cancel electromagnetic interference such that the electromagnetic interference is not applied to the display panel PA.

The circuit board CB may be arranged below the cover panel CP. Various elements such as, for example, a driver, a processor, or the like which drive the display panel PA may be arranged on the circuit board CB.

In an embodiment, a printing pad, a manufacturing apparatus including the printing pad of the cover window, and a manufacturing method of the cover window using the same according to an embodiment of the disclosure, may transfer the ink to the target object to be processed. In an embodiment, the object to be processed may include glass. In an embodiment, the glass may be the cover window CW placed on the display panel PA including the pixels.

In an embodiment, the ink may include a light-shielding material. Accordingly, the light-shielding pattern may be formed on the target object.

In an embodiment, the target object may be coupled with the outer case EDC having a defined space for the target object. The target object coupled with the outer case EDC may be an electronic device for the image display, the wearable electronic device, or the vehicle electronics including the display module (refer to FIG. 3).

In the target object, a curvature may be gradually decreasing. In a case of a conventional manufacturing apparatus of the cover window, as the curvature decreases, the ink might not transfer to the portion having the minimum curvature (hereinafter, a “minimum curvature part”) in the target object. The manufacturing apparatus of the cover window may be elastically deformed upon coming in contact with the target object, transferring the ink to the target object. However, the conventional manufacturing apparatus of the cover window might not be able to deform the elastomer to match the minimum curvature part, causing the formation of a blank part where the ink is not transferred to the target object (hereinafter, referred to as the “un-printed part”). Since no light-shielding material is formed in the un-printed part, the light leak phenomenon may occur through the un-printed part. This light leak phenomenon may interfere with a user's immersive experience when viewing a dark image, or cause problems such as different colors appearing.

Hereinafter, the printing pad with improved printing performance, the manufacturing method of the printing pad, the manufacturing apparatus of the cover window including the printing pad, and the manufacturing method of the cover window using the same may be described in detail. By improving the printing quality, it is possible to prevent the occurrence of the un-printed part and to prevent the occurrence of the light leak phenomenon.

FIG. 6 is a view illustrating the manufacturing apparatus of the cover window according to an embodiment of the disclosure. FIG. 7 is a view illustrating the printing pad included in the manufacturing apparatus of the cover window of FIG. 6.

Hereinafter, the first to third directions D1, D2, and D3 may be different directions from the first to third directions DR1, DR2, and DR3 of FIGS. 3, 4, and 5. For example, the first to third directions D1, D2, and D3 may cross each other. For example, the first to third directions D1, D2, and D3 may be perpendicular to each other.

Referring to FIG. 6, a manufacturing apparatus of the cover window 1 according to an embodiment of the disclosure may include an ink supply part 11, a substrate fixing part 12, and an ink transfer part 13. The manufacturing apparatus of the cover window 1 may be a device for printing ink on an outer surface of the cover glass CG. For example, the manufacturing apparatus of the cover window 1 may include the cover window described below (e.g., the cover window CW of FIG. 25), and may be a device to form the light-shielding pattern.

For example, the ink supply part 11 may include a corrosion plate IP and an ink cup INC. For example, the ink cup INC may have a hole formed therein, through which the ink may flow out. An ink receiving groove IGR may be formed in the corrosion plate IP. If the ink cup INC that receives the ink is placed on the part of the ink supply part 11 that includes the ink receiving groove IGR, the ink may flow out through the hole of the ink cup INC. The ink may spread out over the surrounding areas but cannot remain there and only the ink receiving groove IGR retains the ink due to its recessed shape. After the ink is filled in the ink receiving groove IGR, the ink cup INC may be moved to another location. For example, an ink trace TRA may be a mark formed by the ink that flowed out through the hole of the ink cup INC when the ink cup INC was placed on the ink supply part 11.

For example, the substrate fixing part 12 may include a jig JI. For example, the jig JI may include a base plate BA (hereinafter, referred to as an “ink plate”), a protrusion part PP, and a fastening groove CH. A groove GR may be defined in the jig JI. For example, the groove GR may be formed in the base plate BA. The outer part of the groove GR may be surrounded by the protrusion part PP. The target object (e.g., the cover glass CG) may rest in the groove GR.

For example, the ink transfer part 13 may include a printing head PRH and a printing pad PRP. The printing pad PRP may be connected to the printing head PRH. Depending on a movement of the printing head PRH, the printing pad PRP may receive the ink from the ink supply part 11 and transfer the ink to the target object fixed to the substrate fixing part 12. In one embodiment, the ink transfer part 13 may contact the ink receiving groove, then contact the target object fixed to the substrate fixing par 12 before the ink dries.

Referring to FIG. 7, the printing pad PRP according to an embodiment of the disclosure may have a multi-stage structure. In an embodiment, the printing pad PRP may include a first part PA1 and a second part PA2 that extend from the support part SU.

For example, height ratios of the second part PA2, the first part PA1, and the support part SU may be about 15% to about 25%, about 35% to about 45%, and about 35% to about 45%. For example, a boundary between the first part PA1 and the second part PA2 may be positioned at about 25% to about 40% of a sum of a height of the first part PA1 and a height of the second part PA2 measured from the second upper surface UP2. Accordingly, the height of the second part PA2 may be smaller than the height of the first part PA1, as shown in FIG. 7. However, the disclosure is not limited thereto. For example, the height ratios may be modified depending on the minimum curvature of the target object, the material included in the target object, a hardness of the printing pad PRP, or the like.

For example, the support part SU may connect the printing pad PRP to the printing head PRH. In some embodiments, the support surface SS0 may have two surfaces that are parallel to each other and separated in the third direction D3.

In an embodiment, the target object may include the display surface (e.g., DPS of FIG. 9) and the sidewall extending from the display surface in the third direction (e.g., SW of FIG. 9). The printing pad PRP may transfer the ink to a portion of the display surface and to the entire sidewall.

In an embodiment, the first part PA1 and the second part PA2 may include an elastomer. In an embodiment, the first part PA1 and the second part PA2 may include silicone.

In an embodiment, the first part PA1 may include a bottom surface BS parallel to a plane defined by the first direction D1 and the second direction D2, a first upper surface UP1 facing the bottom surface BS, and a first side surface SS1 connecting the bottom surface BS and the first surface UP1.

In an embodiment, the second part PA2 may include a second upper surface UP2 facing the first upper surface UP1, and a second side surface SS2 connecting the first upper surface UP1 and the second upper surface UP2. In an embodiment, the second side surface SS2 may include a contact part CP having a radius of curvature that is equal to the minimum curvature radius of the target object.

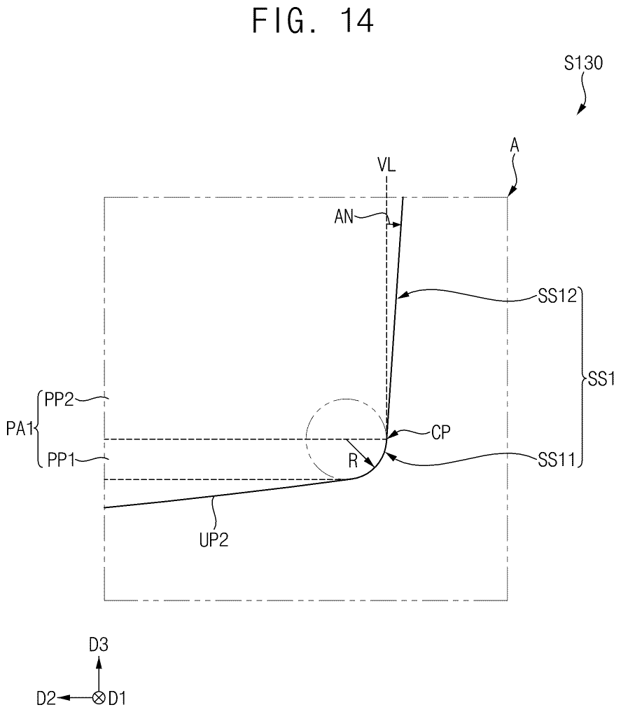

In an embodiment, the second pat PA2 increases in width WD2 as measured in the second direction D2 going from the second upper surface UP2 to the first upper surface UP1, such that the second side surface SS2 forms a preselected angle (e.g., AN of FIG. 14) with respect to a virtual normal line VL perpendicular to the bottom surface BS. For example, a width of the first part PA1 may range from about 102% to about 110%. For example, the bottom surface BS may have a width that is 110% of the width of the second upper surface UP2.

In a case of a printing pad according to a comparative example, a part corresponding to the first part PA1 (i.e., the part used for printing) may have an undercut structure (e.g., a shape that becomes concave and convex from a part corresponding to the bottom surface). For example, if the width of the first part PA1 compared to the second part PA2 exceeds about 110%, or if the width of the first part PA1 is less than about 102% of the width of the second part PA2, the second part PA2 might not deform sufficiently when pressed against the target object, resulting in the un-printed part. The “I” shape refers to a form in which the widths of the second part PA2 and the first part PA1 are approximately the same. The un-printed part may occur because the second part PA2 is not sufficiently supported, or the printing pad PRP does not touch the minimum curvature part of the target object.

In an embodiment, the preselected angle (e.g., IN of FIG. 14) between the virtual normal line VL and the second side surface SS2 may be about 2 degrees to about 4 degrees, inclusive. A detailed explanation of this is described below in reference to FIG. 14.

In an embodiment, the first part PA1 may have a first Shore A hardness, and the second part PA2 may have a second Shore A hardness. In an embodiment, the second Shore A hardness may be less than the first Shore A hardness. In an embodiment, the second Shore A hardness may be about 70% to about 90% of the first Shore A hardness. The first part PA1 may have a hardness of about 20 Shore A, and the second part PA2 may have a hardness of about 25 Shore A.

For example, if the second Shore A hardness is less than about 70% of the first Shore A hardness, an air pocket may form at the minimum curvature part when the printing head PRH presses on the target object. In this case, the minimum curvature part may be un-printed due to the air pocket (i.e., causing the light leak phenomenon by the formation of the un-printed part).

For example, when the second Shore A hardness exceeds about 90% of the first Shore A hardness, it is as though the first part PA1 and the second part PA2 have the same hardness. Thus, the printing head PRH might not deform sufficiently. In this case, the ink might not transfer to the minimum curvature part, and the light leakage phenomenon may occur due to the formation of the un-printed part.

As the first part PA1 has a greater hardness than the second part PA2, the first part PA1 may support the second part PA2 more stably.

As the second part PA2 has a lower hardness than the first part PA1, the second part PA2 may deform sufficiently in response to pressure to transfer the ink to the minimum curvature part.

FIG. 8 is a flow chart illustrating the manufacturing method of the printing pad according to an embodiment of the disclosure. FIGS. 9, 10, 11, 12, 13, and 14 are views illustrating the manufacturing method of the printing pad of FIG. 8.

Now, with reference to FIGS. 1, 2, 3, 4, 5, 6, and 7, the overlapping description with the description of the printing pad and the manufacturing apparatus of the cover window including the same may be omitted or simplified.

Referring to FIG. 8, the manufacturing method of the printing pad according to an embodiment of the disclosure 2 may include setting a design criteria including a minimum curvature radius of a target object (S110), forming a second part including a second upper surface, a second side surface extending from the second upper surface in a third direction, and a contact part having a curvature radius equal to a minimum curvature radius of the target object (S120), forming a first part on the second part, and including a first upper surface facing the second upper surface in the third direction, a bottom surface facing the first upper surface in the third direction and parallel to a surface defined by a first direction and a second direction that cross the third direction, and a first side surface connecting the bottom surface and the first upper surface (S130).

Referring to FIGS. 7, 8, and 9, the design criteria may be set that includes a minimum curvature radius R1 of the target object (e.g., the cover glass CG) (S110). In order to design the contact part CP, which is the most convex part of the printing pad PRP that transfers the ink to the target object, to have a radius of curvature that is equal to the minimum curvature radius of the target object, the minimum curvature radius of the target object may be obtained first.

For example, the target object may have a different radius of curvature depending on a measurement location of an inner side surface IS. For example, the target object may have a first curvature radius R1 and a second curvature radius R2. For example, the first curvature radius R1 may be the minimum curvature radius of the target object.

In an embodiment, the target object to be processed may include a glass (e.g., the cover glass CG of FIG. 9), and the glass may be a cover window (e.g., the cover window CW of FIGS. 3 and 4) which is placed on the display panel (e.g., the display panel PA of FIGS. 3 and 4).

In an embodiment, the cover glass CG may include the display surface DPS, and the sidewall SW extending from the display surface DPS in the third direction D3. In the following description, for convenience, a highest portion of the sidewall SW may be referred to as a top surface TS, an inner surface of the sidewall SW as an inner side surface IS, and an inner surface of the display surface DPS as the inner surface of the display surface DPS (e.g., IF of FIG. 24).

The sidewall SW may have a preselected (predetermined) height (D). For example, the sidewall SW may transfer the ink on the front surface.

The cover lass CG may have a first width W1. For example, the cover glass CG may allow the ink transfer to only partially, such as by a portion (e.g., a second width W2). For example, a center of the inner surface may have light-transmitting property, and 2-1 width W21 and 2-2 width W22 near the sidewall may be covered by the light-shielding material and thus have non light-transmitting (i.e., light-shielding) property.

Referring to FIGS. 7, 8, 10, and 11, in an embodiment, it is possible to first form the second part PA2. The second part PA2 may include the second upper surface UP2 and the second side surface SS2. The second side surface SS2 may extend from the second upper surface UP2 in the third direction DR3. The second side surface SS2 may include a contact part CP having the curvature radius R equal to the minimum curvature radius of the target object (S120).

In an embodiment, the second part PA2 may be formed by supplying an elastomer M1 in a mold MO. In an embodiment, the second part PA2 may include silicone. For example, an interior of the mold MO may have a hollow space MS. In this case, the hollow space MS may have a curved shape so that the second part PA2 has the radius of curvature R equal to the minimum curvature radius of the target object.

In an embodiment, the second side surface SS2 may be formed so that the width WD2 of the second part PA2 between the contact part CP to the first upper surface UP1 in the second direction D2 increases with distance from the contact part CP. In an embodiment, the second side surface SS2 from the contact part CP to the first upper surface US1 may be formed to have an angle of about 2 degrees to about 4 degrees, inclusive, relative to the vertical normal line VL parallel to the third direction DR3. For this purpose, in the cross-sectional view, the portion of the mold MO may have slopes corresponding to the desired slopes of the first part PA1 and the second part PA2.

Referring to FIGS. 8, 12, 13, and 14, it is possible to form the first part PA1 on the second part PA2. The first part PA1 may include a first upper surface UP1 facing the second upper surface UP2 in the third direction DR3, a bottom surface BS facing the first upper surface UP1 in the third direction DR3 and parallel to a plane defined by a first direction DR1 and a second direction that crosses the third direction DR3, and a first side surface SS1 connecting the bottom surface BS and the first upper surface US1 (S130).

In an embodiment, the first part PA1 may be formed by supplying an elastomer M2 in a mold MO. In an embodiment, the first part PA1 may include silicone.

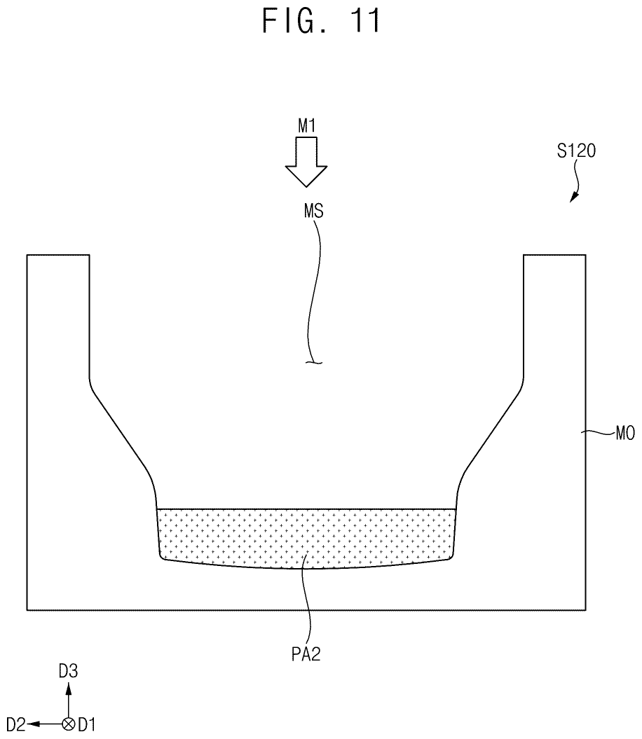

As shown in FIGS. 11 and 12, the elastomer M1 forming the second part PA2 and the elastomer M2 forming the first part PA1 may be different from each other. In an embodiment, the second Shore A hardness may be lower than the first Shore A hardness. In an embodiment, the second Shore A hardness may be about 70% to about 90% of the first Shore A hardness. In an embodiment, the first Shore A hardness and the second Shore A hardness may be adjusted by an addition of silicone oil to the first part PA1 and the second part PA2. By adding the silicone oil before curing, final hardness of the printing pad PRP may be adjusted. To this end, the printing pad PRP having the multi-stage structure with different hardness levels using single silicone material.

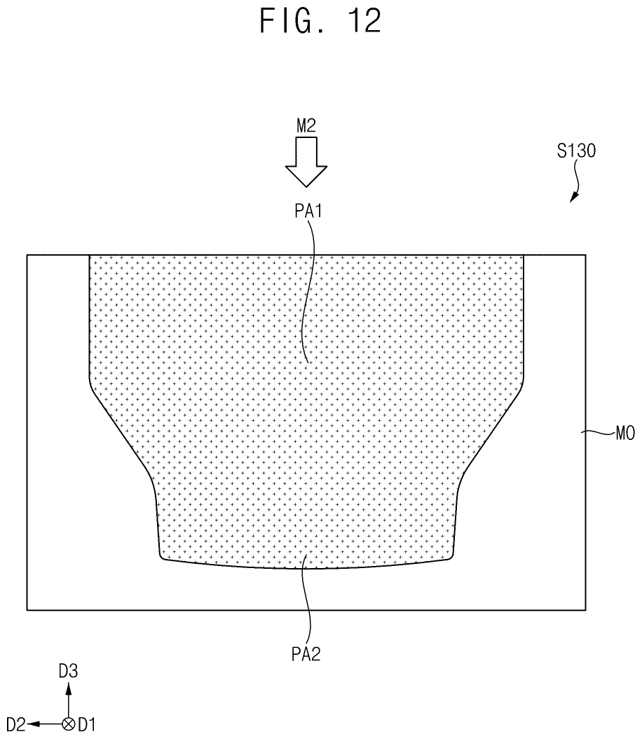

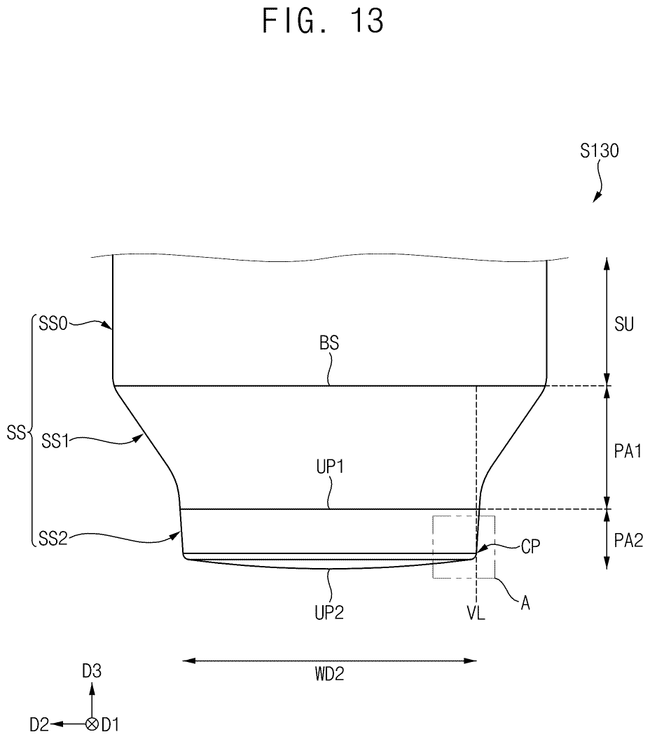

To this end, the printing pad (e.g., the PRP of FIG. 7) shown in FIGS. 13 and 14 may be formed. For example, as shown in FIG. 14, it is possible to have a first body PP1 from the second upper surface UP2 to the contact part CP relative to the contact part CP, and a second body PP2 from the contact part CP to the support part SU. A 1-1 side surface SS11 of the first body PP1 and a 1-2 side surface SS12 of the first body may form a rounded corner.

In an embodiment, the angle between the second side surface (e.g., the 1-2 side surface SS12) and the vertical normal VL may be between about 2 degrees and about 4 degrees, inclusive.

For example, if the angle between the 1-2 side surface SS12 and the virtual normal line VL is less than about 2 degrees, the printing pad may have a shape that is close to the right angle. In this case, even if the printing pad is deformed, it might not reach the minimum deformation part (minimum curvature radius part) of the target object. Accordingly, the light leakage phenomenon according to the un-printed part may occur.

The printing pad may transfer the ink first to the display surface (e.g., the display surface DPS of FIG. 9), then to the sidewall (e.g., the sidewall SW of FIG. 9), and then the top surface (e.g., the top surface TS of FIG. 9). However, if the angle between the 1-2 side surface SS12 and the virtual normal line VL exceeds about 4 degrees, the ink may transfer to the sidewall (e.g., the sidewall SW of FIG. 9) before the display surface. The air pocket may be formed at the minimum deformation. As a result, the light leakage phenomenon according to the un-printed part may occur.

In the case of the manufacturing apparatus of the cover window according to the comparative example, the printing pad may have an undercut shape. With the undercut shape, the printing pad does not touch the minimum curvature part, resulting in the un-printed part. If an additional printing process is carried out to remove the un-printed part, time and cost of the additional printing process may be incurred, and a problem of thickness increase by the additional ink may occur. In addition, even if the additional printing process is carried out, the un-printed part may still exist.

On the other hand, in the case of a manufacturing apparatus of the cover window according to a comparative example, the printing pad may have a convex shape. The convex shape might not have the same shape as the minimum curvature part of the target object. In this case, the printing pad still does not touch the minimum curvature part, resulting in the un-printed part. As described above, in order to remove the un-printed part, the additional printing process (e.g., 3 strokes or more), the time and cost of the additional printing process may be consumed, and the problem of thickness increase due to the additional ink may occur. In addition, even if the additional printing process is carried out, the un-printed part may still exist.

However, the printing pad according to an embodiment of the disclosure (e.g., PRP of FIG. 7) has a second part PA2 having a hardness of about 70% to about 90% of the first part PA1, and the angle between the 1-2 side surface SS12 and the virtual normal line VL may be between about 2 degrees and about 4 degrees, inclusive, so that the ink may be transferred to the portion of the display surface and to the entire sidewall. The printing pad may transfer the ink to the portion of the display surface of the target object and the entire sidewall even with two strokes.

FIG. 15 is a flow chart illustrating the manufacturing method of the cover window using the manufacturing apparatus of the cover window of FIG. 6. FIGS. 16, 17, 18, 19, 20, 21, 22, and 23 are views illustrating the manufacturing method of the cover window of FIG. 15.

Hereinafter, overlapping descriptions of the printing pad and the manufacturing apparatus of the cover window using the same with reference to FIGS. 1, 2, 3, 4, 5, 6, and 7, and the manufacturing method of the printing pad with reference to FIGS. 8, 9, 10, 11, 12, 13, and 14, will be omitted or abbreviated.

Referring to FIG. 15, a manufacturing method of the cover window according to an embodiment of the disclosure 3 include providing an ink to an ink plate (S210), placing a target object to be processed on a stage (S220), transferring the ink to the target object using a printing pad including a first part including a bottom surface parallel to a plane defined by a first direction and a second direction crossing the first direction, a first upper surface facing the bottom surface, and a first side surface connecting the bottom surface and the first upper surface, and a second part including a second upper surface facing the first upper surface, a second side surface connecting the first upper surface and the second surface, and including a contact part having a curvature radius equal to a minimum curvature radius of the target object (S230).

Referring to FIGS. 15, 16, and 17, an ink IK may be provided on the ink plate IP. For example, the ink receiving groove IGR may be formed on the corrosion plate IP and the ink cup INC including the ink IK may be placed on it so that the ink IK may be left only in the ink receiving groove IGR (S210).

Referring to FIGS. 15, 18, and 19, the target object (e.g., the cover glass CG) may be placed on the stage (e.g., the jig JI) (S220). For example, the groove GR may be formed in the assembled base plate BA through the fastening groove CH, the protrusion part PP surrounding the groove GR in the third direction D3 may be formed, and a chuck (e.g., a vacuum chuck VC) for fixing the target object (e.g., the cover glass CG) may be placed in the groove GR, for example, the vacuum chuck VC may vacuum adsorb the target object (e.g., the cover glass CG) and prevent a shaking of the target object (e.g., the cover glass CG) during the printing process.

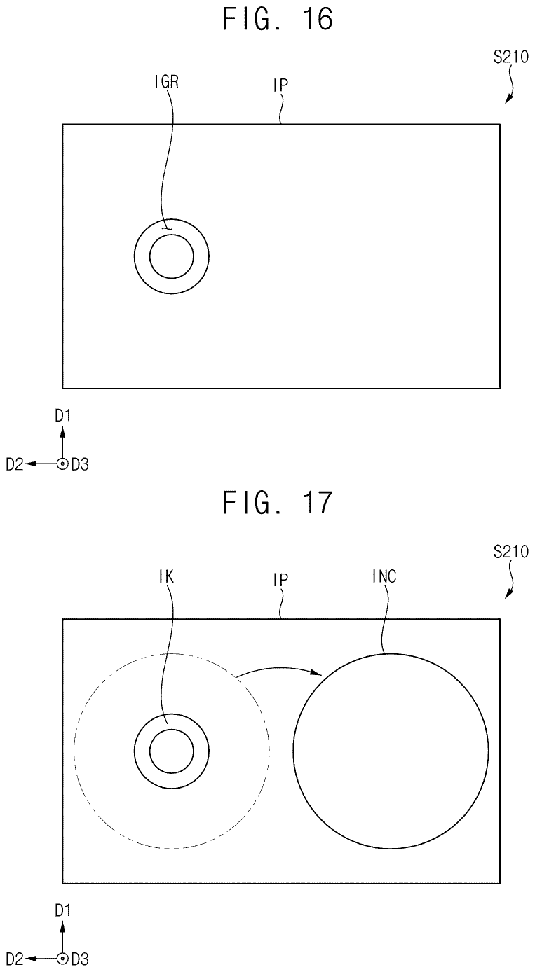

For example, the ink cup INC may have a hole at its bottom through which ink may flow out. When the ink cup INC containing the ink is placed on the corrosion plate IP, the ink may flow out through the hole of the ink cup INC, and only the ink receiving groove IGR may retain the ink. After the ink is filled into the ink receiving groove IGR, the ink cup INC may be moved to another location. For example, in FIG. 17, a dotted line indicates a position where the ink cup INC is placed to fill the ink into the ink receiving groove IGR, and a solid line indicates the position to which the ink cup INC is moved after the ink has been filled into the ink receiving groove IGR.

Referring to FIGS. 15, 20, 21, 22, and 23, the ink IK may be transferred to the target object (e.g., the cover glass CG) using the printing pad PRP (S230). First, the printing head PRH connected to the printing pad PRP may be moved to transfer the ink IK to the printing pad PRP. In one embodiment, the ink transfer part 13 may contact the ink receiving groove, then contact the target object fixed to the substrate fixing par 12 before the ink dries.

FIGS. 24, 25, 26, and 27 are views illustrating an effect of the printing pad according to embodiments of the disclosure.

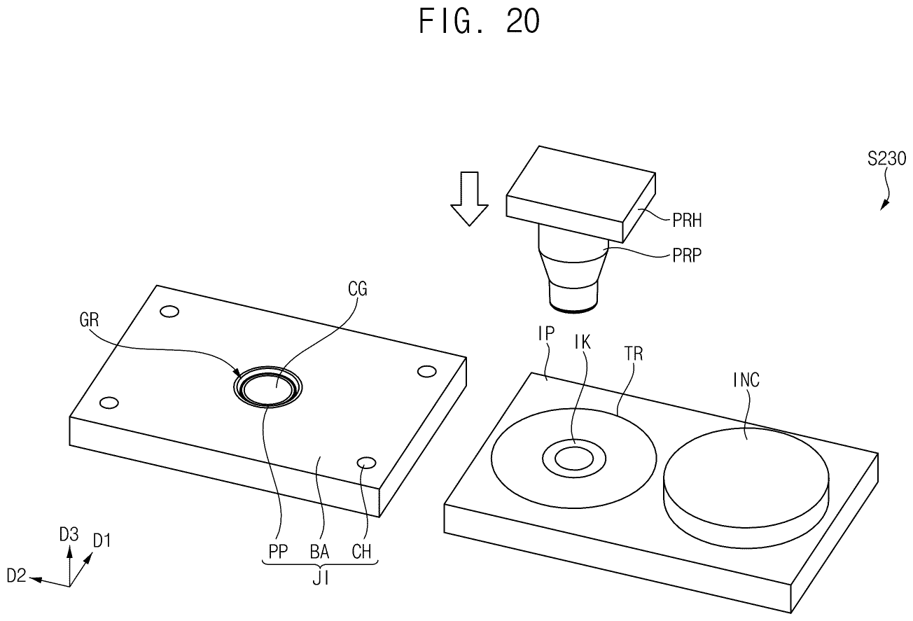

Referring to FIGS. 20, 21, 22, 23, and 24, the printing pad PRP may first form a first ink layer BM1 on the cover glass CG. As described above, the inner surface IS of the target object, such as the cover glass CG, may include a first inner surface IS1 that includes the minimum curvature part, and a second inner surface IS2 that extends in the third direction D3 from the first inner surface IS1. A preliminary cover window CW′ may prevent the ink transfer onto the minimum curvature part of the first inner surface IS1. Therefore, an additional printing process may be performed.

Referring to FIGS. 20, 21, 22, 23, and 25, the second ink layer BM2 may be formed through the additional printing process. The second ink layer BM2 may be extended to an inner surface IF of the display surface DPS (shown in FIG. 25), unlike the first ink layer BM1 (shown in FIG. 24).

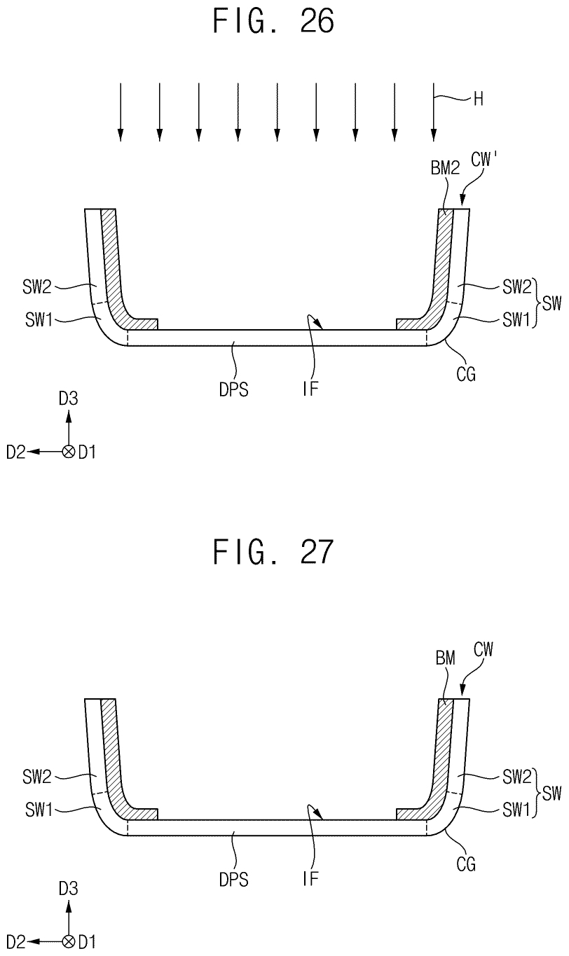

Referring to FIGS. 26 and 27, an additional printing layer (i.e., the second ink layer BM2) may be cured by applying heat H. Accordingly, the cover window CW with a light-shielding pattern BM may be formed.

As described above, the manufacturing method of the cover window according to an embodiment of the disclosure may transfer the ink to the portion of the display surface and the entire sidewall in just two strokes. In addition, the ink may be transferred to the minimum curvature part of the cover window to prevent the occurrence of the light leakage phenomenon by the un-printed part.

The printing pad according to exemplary embodiments of the disclosure may be applied to the process of manufacturing display devices included in computers, laptops, mobile phones, smartphones, smart pads, PMPs, PDAs, MP3 players, or the like.

Although the embodiments of the disclosure have been explained above, it is understood that a person with ordinary knowledge in the field of technology may modify and modify the disclosure in various ways within the scope of the idea and area of the disclosure described in the patent claims below.

What is claimed is:

1. A printing pad including:
a first part including:
a bottom surface parallel to a plane defined by a first direction and a second direction crossing the first direction,
a first upper surface facing the bottom surface, and
a first side surface connecting the bottom surface and the first upper surface; and
a second part including:
a second upper surface facing the first upper surface,
a second side surface connecting the first upper surface to the second surface, and
a contact part having a radius of curvature that is equal to a minimum curvature radius of a target object.

2. The printing pad of claim 1, wherein the second side surface increases in width, the width measured in the second direction, in going from the second upper surface to the first upper surface, and forming a preselected angle with respect to a virtual normal line perpendicular to the bottom surface.

3. The printing pad of claim 2, wherein the selected angle between the virtual normal line and the second side surface is about 2 degrees to about 4 degrees, inclusive.

4. The printing pad of claim 1, wherein,
the first part has a first Shore A hardness,
the second part has a second Shore A hardness, and
the second Shore A hardness is lower than the first Shore A hardness.

5. The printing pad of claim 4, wherein the second Shore A hardness is about 70% to about 90% of the first Shore A hardness.

6. The printing pad of claim 1, wherein, the first part and the second part include an elastomer.

7. The printing pad of claim 6, wherein the first part and the second part contain silicone.

8. A method of manufacturing a printing pad, the method including:
setting a design criteria including a minimum curvature radius of a target object to be processed;
forming a second part including a second upper surface, a second side surface extending from the second upper surface in a third direction, and a contact part having a radius of curvature that is equal to a minimum curvature radius of the target object; and
forming a first part on the second part, the first part including a first upper surface facing the second upper surface in the third direction, a bottom surface facing the first upper surface in the third direction and parallel to a plane defined by a first direction and a second direction that cross the third direction, and a first side surface connecting the bottom surface and the first upper surface.

9. The method of claim 8, wherein the second side surface is formed so that a width measured in the second direction increases in going from the contact part to the first upper surface.

10. The method of claim 9, wherein the second side surface is formed to have an angle of about 2 degrees to about 4 degrees, inclusive, with a virtual normal line parallel to the third direction, from the contact part to the first upper surface.

11. The method of claim 8, wherein the first part and the second part are formed by supplying an elastomer in a mold.

12. The method of claim 11, wherein,
the first part has a first Shore A hardness,
the second part has a second Shore A hardness, and
the second Shore A hardness is lower than the first Shore A hardness.

13. The method of claim 12, wherein the second Shore A hardness is about 70% to about 90% of the first Shore A hardness.

14. The method of claim 12, wherein the first Shore A hardness and the second Shore A hardness are controlled by an addition of silicone oil to the first part and the second part, respectively.

15. A method of manufacturing a cover window, the method including:
providing an ink to an ink plate;
placing a target object to be processed on a stage;
transferring the ink to the target object using a printing pad including a first part and a second part, the first part including a bottom surface parallel to a plane defined by a first direction and a second direction crossing the first direction, a first upper surface facing the bottom surface, and a first side surface connecting the bottom surface and the first upper surface, and the second part including a second upper surface facing the first upper surface, a second side surface connecting the first upper surface and the second surface, and a contact part having a radius of curvature that is equal to a minimum curvature radius of the target object.

16. The method of claim 15, wherein a second Shore A hardness of the second part is lower than a first Shore A hardness of the first part.

17. The method of claim 15, wherein,
the target object includes glass, and
the glass is a cover window for a display panel.

18. The method of claim 17, wherein,
the target object is coupled with an outer case having a space to receive the target object, and
the target object combined with the outer case is one of an image display, a wearable electronic device, or a vehicle electronic device including a display module.

19. The method of claim 16,
wherein the target object includes:
a display surface; and
the sidewall extending in the third direction that crosses the first direction and the second direction, and
the printing pad transfers the ink onto a portion of the display surface and the entire sidewall.

20. The method of claim 12, wherein the ink includes a light-shielding material.
